(19) United States
(12) Patent Application Publication
(10) Pub. No.: US 2015/0252491 A1
(43) Pub. Date: Sep. 10, 2015

(54) Apparatus for manufacturing ingot and method of manufacturing ingot

(71) Applicants: Hyun Goo Kwon, Uiwang (KR); Yeo Kyun Yoon, Hwaseong (KR); Min Soo Son, seoul (KR)

(72) Inventors: Hyun Goo Kwon, Uiwang (KR); Yeo Kyun Yoon, Hwaseong (KR); Min Soo Son, seoul (KR)

(73) Assignee: Technovalue Co., LTD., Seoul (KR)

(21) Appl. No.: 14/257,141

(22) Filed: Apr. 21, 2014

(30) Foreign Application Priority Data
Mar. 7, 2014 (KR) 10-2014-0027408

(51) Int. Cl. C30B 15/20; C30B 15/00

(52) U.S. Cl. CPC C30B 15/20; C30B 15/002

(57) ABSTRACT

Disclosed are an apparatus for manufacturing an ingot and a method of manufacturing the ingot to control a concentration of dopant. The apparatus for manufacturing an ingot to intermittently or continuously feed silicon while an ingot is grown, includes: a crucible having a melting zone in which the silicon and dopant are melted; an inner wall surrounded by the crucible, and having a growth zone in which the melted silicon and the dopant are introduced so that the ingot is grown in the inner zone; and a feeding unit feeding the silicon into the melting zone, wherein a ratio of a feed rate of the silicon fed through the feeding unit to a growth rate of the ingot is changed.

### BACKGROUND OF THE DISCLOSURE

1. Field of the Disclosure

The present invention relates to an apparatus for manufacturing an ingot and a method of manufacturing the ingot.

2. Description of the Related Art

An ingot is important to manufacture a semiconductor chip or a solar cell. The ingot is manufactured through a procedure of melting silicon in a crucible and then solidifying the melted silicon.

The ingot is manufactured by a Czochralski method. According to the Czochralski method, the ingot is manufactured by solidifying silicon attached around a bar or a seed crystal penetrated in molten silicon while slowly elevating the bar or the seed crystal.

In recent years, a research on an apparatus for manufacturing an ingot by a continuous Czochralski method capable of manufacturing a plurality of ingots by successively feeding silicon has been performed.

### SUMMARY

The present invention provides an apparatus for manufacturing an ingot and a method of manufacturing the ingot to easily control a concentration of dopant.

Objects of the embodiment may not be limited to the above, and other objects which are not described may be clearly comprehended to those of skilled in the art to which the embodiment pertains through the following description.

In accordance with an aspect of the present invention, an apparatus for manufacturing an ingot to intermittently or continuously feed silicon while an ingot is grown includes: a crucible having a melting zone in which the silicon and dopant are melted; an inner wall surrounded by the crucible, and having a growth zone in which the silicon and the dopant melted in the crucible are introduced so that the ingot is grown in the inner zone; and a feeding unit to feed the silicon into the melting zone, wherein a ratio of a feed rate of the silicon fed through the feeding unit to a growth rate of the ingot is changed.

The feeding unit may reduce a feed amount of the silicon when a concentration of the dopant in the growth zone is reduced during a procedure of growing the ingot.

As a segregation coefficient of the dopant is smaller, feeding of the dopant into the melting zone may stop or the number of times of the feeding of the dopant may be reduced.

The dopant may have a segregation coefficient less than 0.4, and the feeding of the dopant may stop while growth of the ingot is completed after the dopant is fed into the crucible before the ingot is grown.

The dopant may have a segregation coefficient of 0.4 or greater, and the dopant may be fed into the melting zone at least one time while the ingot is grown.

The dopant may be fed into the melting zone through the feeding unit.

A concentration of the dopant in the ingot may be maintained by varying the feed rate of the silicon fed from the feeding unit according to the concentration of the dopant of the growth zone.

When the ingot is grown during a first time period and a second time period which is a consecutive period to the first time period, a level of the melted silicon may be gradually increased during the first time period, and may be gradually reduced during the second time period.

An initial value of the ratio may be greater than 1.

In accordance with an aspect of the present invention, an apparatus for manufacturing an ingot to intermittently or continuously feed silicon while an ingot is grown further includes: a feed regulator which is connected to the feeding unit, to regulate a feed amount of the silicon; a first hopper which is connected to the feed regulator, to store the silicon; and a second hopper to feed silicon stored in the second hopper into the crucible after the growth of the ingot is completed, wherein a hopper feed rate of the silicon fed from the second hopper is greater than a regulation feed rate of the silicon fed from the feed regulator.

In accordance with another aspect of the present invention, an apparatus for manufacturing an ingot to intermittently or continuously feed silicon while an ingot is grown includes: a crucible having a melting zone in which the silicon and dopant are melted; an inner wall surrounded by the crucible, and having a growth zone in which the silicon and the dopant melted in the crucible are introduced so that the ingot is grown in the growth zone; and a feeding unit to feed the silicon into the melting zone with a feed rate varying according to a concentration of the dopant in the inner wall. The feed rate is reduced when a concentration of the dopant in the growth zone is reduced during a procedure of growing the ingot.

As a segregation coefficient of the dopant is smaller, feeding of the dopant into the melting zone may stop or the number of times of the feeding of the dopant may be reduced.

The dopant may have a segregation coefficient of 0.4 or greater, and the dopant may be fed into the melting zone at least one time while the ingot is grown.

The dopant has a segregation coefficient less than 0.4, and the feeding of the dopant may stops while the growth of the ingot is completed after the dopant is fed into the crucible before the ingot is grown.

When the growth of the ingot starts, the feed rate may be equal to or greater than a growth rate of the ingot.

The dopant may be fed into the melting zone through the feeding unit.

A concentration of the dopant in the ingot may be maintained by varying the feed rate of the silicon fed from the feeding unit according to the concentration of the dopant of the growth zone.

When the ingot is grown during a first time period and a second time period which is a consecutive period to the first time period, a level of the melted silicon may be gradually increased during the first time period, and may be gradually reduced during the second time period.

In accordance with another aspect of the present invention, an apparatus for manufacturing an ingot to intermittently or continuously feed silicon while an ingot is grown further includes: a feed regulator which is connected to the feeding unit, to regulate a feed amount of the silicon; a first hopper which is connected to the feed regulator, to store the silicon; and a second hopper to feed silicon stored in the second hopper into the crucible after the growth of the ingot is completed, wherein a hopper feed rate of the silicon fed from the second hopper is greater than a regulation feed rate of the silicon fed from the feed regulator.

In accordance with another aspect of the present invention, a method of manufacturing an ingot to intermittently or continuously feed silicon while an ingot is grown includes: melting the silicon and dopant in a melting zone between a crucible and an inner wall surrounded by the crucible; growing an ingot in a growth zone of the inner wall by introducing the melted silicon and dopant in the growth zone; and changing a ratio of a feed rate of the silicon fed into the melting zone to a growth rate of the ingot.

In accordance with another aspect of the present invention, a method of manufacturing an ingot to intermittently or continuously feed silicon while an ingot is grown includes: melting the silicon and dopant in a melting zone between a crucible and an inner wall surrounded by the crucible; growing an ingot in a growth zone of the inner wall by introducing the melted silicon and dopant in the growth zone; and changing a feed rate of the silicon fed into the melting zone according to a concentration of the dopant in the growth zone.

According to an apparatus for manufacturing an ingot and a method of manufacturing the ingot of the embodiment of the present invention, a concentration of dopant can be easily controlled by changing a ratio of a feed rate of silicon to a growth rate of the ingot.

According to an apparatus for manufacturing an ingot and a method of manufacturing the ingot of the embodiment of the present invention, the concentration of the dopant can be easily controlled by changing the feed rate of the silicon according to a concentration of the dopant in a growth zone.

Meanwhile, other various effects may be directly or indirectly disclosed in the following description of the embodiment of the present invention.

### BRIEF DESCRIPTION OF THE DRAWINGS

The objects, features and advantages of the present invention will be more apparent from the following detailed description in conjunction with the accompanying drawings, in which:

FIG. 1 is a view illustrating a configuration of an apparatus for manufacturing an ingot according to an exemplary embodiment of the present invention;

FIG. 2 is a schematic view illustrating an operation of the apparatus for manufacturing an ingot according to an exemplary embodiment of the present invention;

FIG. 3 is a flowchart illustrating an operation procedure of the apparatus for manufacturing an ingot according to an exemplary embodiment of the present invention;

FIGS. 4 and 8 are views illustrating modified examples of the apparatus for manufacturing an ingot according to an exemplary embodiment of the present invention, respectively;

FIG. 5 is graphs illustrating variation in a concentration of dopant according to fed dopant;

FIGS. 6 and 7 are graphs illustrating a concentration of dopant, a feed rate of silicon, and a height of melted silicon in an operation of the apparatus for manufacturing an ingot according to an exemplary embodiment of the present invention; and

FIGS. 9 and 10 are flowcharts illustrating a method of manufacturing an ingot according to an exemplary embodiment of the present invention.

### DETAILED DESCRIPTION OF EXEMPLARY EMBODIMENTS

Exemplary embodiments of the present invention are described with reference to the accompanying drawings in detail. The same reference numbers are used throughout the drawings to refer to the same or like parts. Detailed descriptions of well-known functions and structures incorporated herein may be omitted to avoid obscuring the subject matter of the present invention.

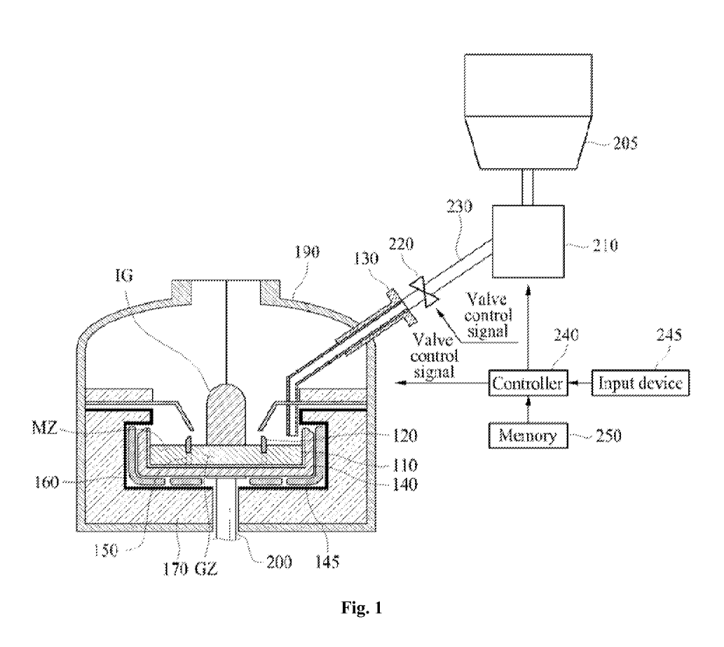

FIG. 1 is a view illustrating a configuration of an apparatus for manufacturing an ingot according to an exemplary embodiment of the present invention. The apparatus for manufacturing an ingot according to an exemplary embodiment of the present invention may be an apparatus for manufacturing an ingot in a Continuous Czochralski method (hereinafter referred to as ‘CCz scheme’) capable of intermittently or continuously feeding silicon while growing the ingot IG.

As shown in FIG. 1, the apparatus for manufacturing an ingot according to an exemplary embodiment of the present invention may include a crucible 110, an inner wall 120, and a feeding unit 130.

The crucible 110 has a melting zone MZ in which silicon and dopant are melted. In this case, the melting zone MZ may be an area between the crucible 110 and the inner wall 120.

The crucible 110 may be made of quartz which prevents the silicon from being polluted and is resistant to a high temperature environment, but the embodiment is not limited thereto.

The inner wall 120 is surrounded by the crucible 110, and has a growth zone GZ in which the silicon and dopant melted in the crucible 110 are introduced so that the ingot IG is grown in the growth zone GZ.

The inner wall 120 may be also made of quartz which prevents the silicon from being polluted and is resistant to a high temperature environment, but the present invention is not limited thereto.

The feeding unit 130 feeds the silicon into the melting zone MZ. The silicon may be intermittently or continuously fed through the feeding unit 130. The feeding unit 130 may be made in the form of a pipe or a tube, but the present invention is not limited thereto.

A susceptor 140 may surround an outer periphery of the crucible 110. Since the silicon is melted at a high temperature, the crucible 110 may soften. The susceptor 140 may service as a support member to maintain a shape of the crucible 110.

The heater 145 heats the crucible in order to melt the silicon fed through the feeding unit 130. The heater 145 may be installed close to the susceptor 140.

The heater 145 may heat the silicon to about 1420° C. being a melting temperature so that the silicon may be melted in the crucible 110. Dopant as well as the silicon may be fed into the crucible 110. If the heater 145 heats the silicon, the dopant as well as the silicon may be melted.

The dopant may include a trivalent material such as phosphorus or a pentavalent material such as boron, but the present invention is not limited thereto.

In this manner, the melted silicon and the dopant may be introduced into the growth zone GZ of the inner wall 120 through an introduction hole 150 of the inner wall 120. The melted silicon is introduced into the growth zone GZ of the inner wall 120 and is slowly cooled at about 1420° C. or lower so that the cooled silicon may be grown as the ingot IG. In this case, the dopant may be distributed into the ingot IG.

A heat-shield 160 and an insulator 170 may insulate heat generated from the heater 145 to improve heat efficiency, and may protect an inner wall of a chamber 190 from radiant heat at a high temperature.

A shaft 200 may be connected to the susceptor 140 to rotate the susceptor 140. The crucible 110 may be also rotated according to the rotation of the susceptor 140. In this case, the ingot IG may be grown while being rotated in a direction opposite to a rotation direction of the shaft 200.

In this case, a ratio of a feed rate of the silicon fed through the feeding unit 130 to a growth rate of the ingot IG is changed.

As the ratio of the feed rate of the silicon fed through the feeding unit 130 to the growth rate of the ingot IG is changed, an amount of the silicon fed from the feeding unit 130 may be changed according to a concentration of the dopant in the growth zone GZ.

It is preferable that the concentration of the dopant is constant with respect to the whole ingot IG after the growth of the ingot IG is completed. The apparatus for manufacturing the ingot in a CCz method may manufacture a plurality of ingots IGs by intermittently or continuously feeding the silicon. In this case, in order to obtain the ingot IG having a constant dopant concentration, according to the intermittent or continuous feeding of the silicon, the dopant may be also intermittently or continuously fed.

In the case of the apparatus for manufacturing the ingot according to the embodiment of the present invention, since the ratio of the feed rate of the silicon to the growth rate of the ingot IG is changed, a dopant concentration in the growth zone GZ may maintain so that the dopant concentration of the ingot IG may be also maintained.

That is, the apparatus for manufacturing the ingot according to the embodiment of the present invention may maintain the dopant concentration of the ingot IG by controlling feeding of the silicon to be relatively easily controlled as compared with the dopant.

In this case, the dopant concentration in the growth zone GZ or the ingot IG may be included in a preset specific concentration range or may maintain as a preset specific concentration.

The dopant may be fed into the crucible 110 in various schemes. For example, after the dopant is fed into the melting zone MZ in a state that a chamber 190 is initially open, the ingot IG may be manufactured.

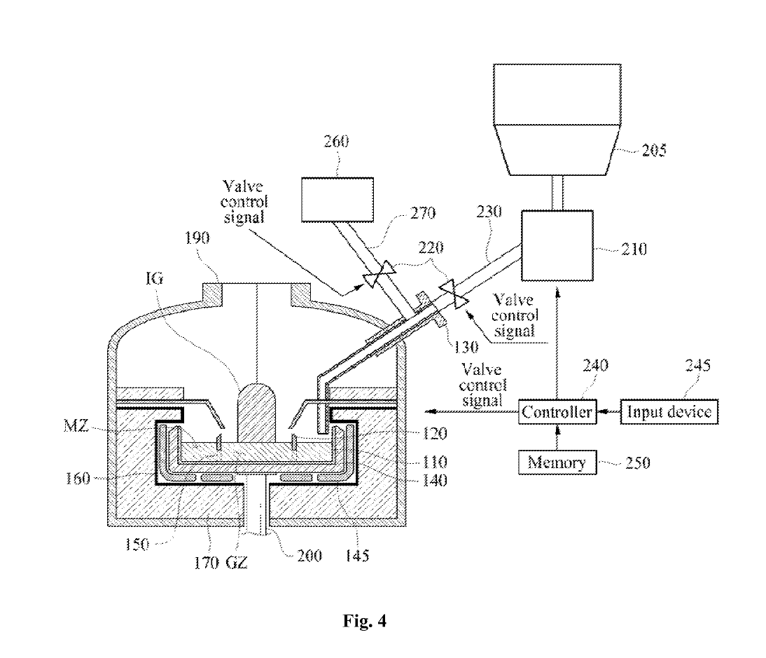

Alternatively, in a state that a dopant feeder 260 is included and the chamber 190 is closed, the dopant from the dopant feeder 260 may be fed into the melting zone MZ. The dopant feeder 260 will be described with reference to FIG. 4 later.

In FIG. 1, a feed regulator 210 may regulate a feed amount of the silicon and may include a vibrator. In this case, the feed regulator 210 may be connected to the feeding unit 130 and regulate a feed amount of the silicon.

A first hopper 250 may be connected to the feed regulator 210 and store the silicon. A valve 220 may be installed at a silicon feed pipe 230 to feed and stop the silicon.

The silicon feed pipe 230 may connect the feed regulator 210 to the feeding unit 130. A controller 240 controls the feed regulator 210 and outputs a valve control signal to control the valve 220.

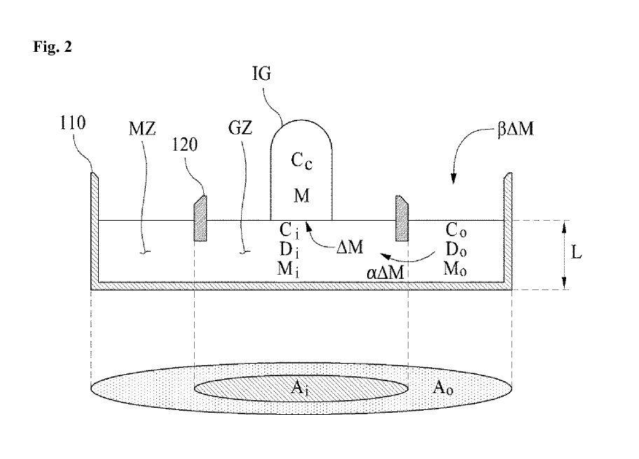

FIG. 2 is a schematic view illustrating an operation of the apparatus for manufacturing an ingot according to an exemplary embodiment of the present invention.

In FIG. 2, A Cc represents a concentration of dopant in the ingot IG, and an M represents a mass of the silicon in a grown ingot IG.

A Co, a Do, and a Mo represent a concentration of the dopant, the number of dopants, and a mass of the silicon in the melting zone MZ, respectively.

A Ci, a Di, and a Mi represent a concentration of dopant, the number of dopants, and a mass of the silicon melted in the growth zone GZ, respectively.

In this case, Di=MiCi and Do=MoCo. Use of the equations will be described in detail later.

A ΔM represents a unit amount of the silicon used to grow the ingot IG, and a βΔM, that is, ΔM_{F} represents an amount of the silicon fed into the melting zone MZ from the outside.

A β represents a feeding coefficient. The β will be described in detail later.

A αΔM represents an amount of the melted silicon introduced into the growth zone GZ from the melting zone MZ.

An Ao and an Ai represent a sectional area of the melting zone MZ and a sectional area of the growth zone GZ, respectively. Further, a p may be Ai/(Ai+Ao), and a q may be Ao/(Ai+Ao).

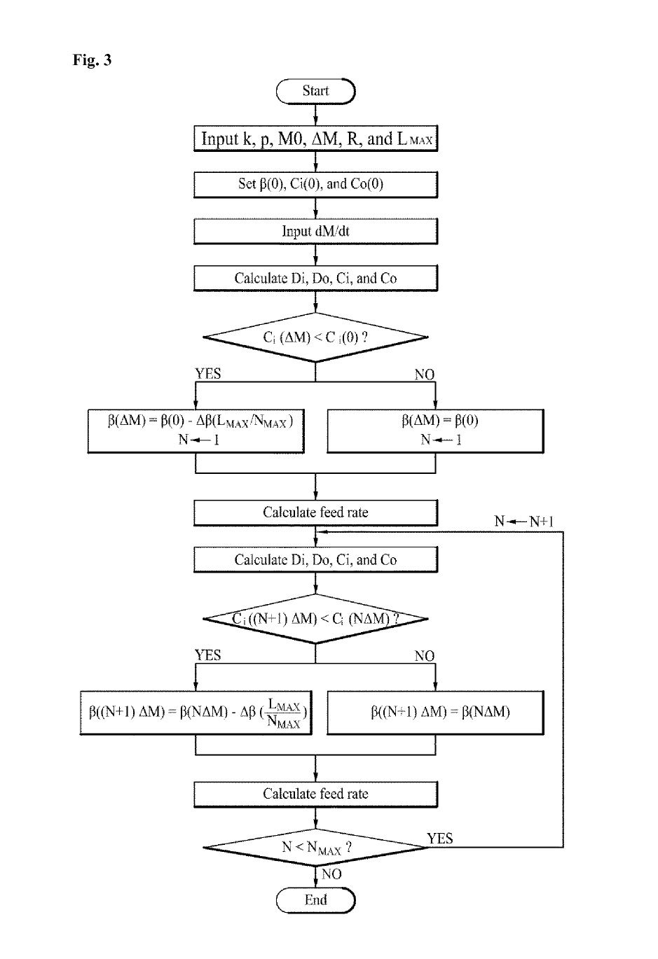

Next, relationships between the concentration of the dopant, the feeding coefficient, and feed of the silicon will be described with reference to FIGS. 2 and 3.

FIG. 3 is a flowchart illustrating an operation procedure of the apparatus for manufacturing an ingot according to an exemplary embodiment of the present invention.

Since a resistivity of the ingot IG is mainly determined according to a concentration Cc of the dopant in the ingot IG, the Ci should be maintained so that the resistivity of the ingot IG is included in a preset range or is maintained at a specific resistivity.

The apparatus for manufacturing the ingot according to the embodiment of the present invention may maintain the concentration Cc of the dopant and the resistivity of the ingot IG by maintaining the Ci.

A k, a p, a M0, a ΔM, an R, and a L_{MAX} may be input. The above informations may be input through an input device 245 such as a keyboard or a touch screen.

In this case, the k represents a segregation coefficient of the dopant, and the R represents a radius of the ingot IG to be manufactured.

In addition, a L_{MAX} represents a maximum length of the ingot IG to be manufactured. Accordingly, the L_{MAX} may be a length of a grown ingot.

Further, the M0 represents an amount of the silicon initially filled in the melting zone MZ and the growth zone GZ, that is, Mi(0)+Mo(0). Since the p and the ΔM were described previously, the detailed description thereof is omitted.

The controller 240 may calculate the M_{MAX}. In this case, the M_{MAX} is the maximum mass of the ingot IG, which may be 2.33πR²L_{MAX}. Further, the controller 240 may calculate the N_{MAX}. In this case, the N_{MAX} may be M_{MAX}/ΔM.

As described above, the ΔM represents a unit amount of the silicon used to grow the ingot IG in the growth zone GZ. Since the N_{MAX} is a ratio of the maximum mass M_{MAX} of the ingot to the unit amount ΔM of the silicon, when ΔM_{F} (=βΔM) is calculated each time the ΔM is used, the N_{MAX} may become the maximum number of times in calculation by the controller 240.

As described above, in the case of the apparatus for manufacturing the ingot according to the embodiment of the present invention, the ratio of the feed rate of the silicon fed through the feeding unit 130 to the growth rate of the ingot IG is changed.

To this end, the feeding unit 130 feeds the silicon into the melting zone MZ with a feed rate which is varied according to the concentration of the dopant in the inner wall having the growth zone GZ. For example, the feeding unit 130 may feed the silicon so that the feeding coefficient β varies according to the concentration of the dopant in the growth zone GZ.

In this case, the feeding coefficient β may be a ratio of an amount ΔM_{F} of the silicon fed into the melting zone MZ from the outside through the feeding unit 130 to a unit amount ΔM of the silicon used to grow the ingot IG in the growth zone GZ.

Since the feeding coefficient β is the ratio of the ΔM_{F} to the ΔM, when the growth rate of the ingot is dM/dt, the feed rate dM_{F}/dt of the silicon may be β(dM/dt).

The foregoing N_{MAX} may be a maximum value of the number of times in calculation with respect to the feed rate of the silicon fed from the feeding unit 130 according to the concentration of the dopant. That is, since the amount of the silicon fed from the feeding unit 130 may be controlled according to the feed rate, the controller 240 may calculate the feed rate maximum N_{MAX} times according to the concentration of the dopant.

For example, when the M_{MAX} is 200 kg and the ΔM is kg, the N_{MAX} may become 10. Accordingly, the controller 240 may control a feed amount of the silicon by calculating the feed rate of the silicon fed from the feeding unit 130 maximum 10 times.

An initial value of the feeding coefficient β(0), an initial concentration Ci(0) of the dopant in the growth zone GZ, and an initial concentration Co(0) of the dopant in the melting zone MZ may be set. The growth rate dM/dt of the ingot may be input to the controller 240.

A value stored in the memory 250 may be input to the controller 240 or a value may be input to the controller 240 through the input device 245 as the growth rate dM/dt of the ingot. Further, β(0), Ci(0), and Co(0) may be set as values input to the controller 240 through the input device 245 or a value stored in the memory 250. Hereinafter, the Ci(0) and the Co(0) are set as 1 for the purpose of convenience in the description.

The controller 240 may calculate Di, Do, Ci, and Co based on the above input or preset information. So as to calculate the Di, the Do, the Ci, and the Co, an equation described in the Mitsubishi document, J. Cryst. Growth 135, 359, Ono et al. may be used. A following equation 1 and a following equation 8 may be derived according to the Mitsubishi document.

The Di and the Ci are calculated and then the Do and the Co are calculated.

Di(M+ΔM)=Di(M)+α(M)Co(M)ΔM−kCi(M)ΔM [Equation 1]

The Di(M+ΔM) represents the number of dopants in the growth zone GZ when the ingot is grown by M+ΔM. The Di(M) represents the number of dopants in the growth zone GZ when the ingot is grown by M.

In this case, since the number of dopants in the growth zone GZ is Di(ΔM) when the growth of the ingot IG starts so that the melted silicon is used to grow the ingot IG by ΔM, and the Ci(0) and the Co(0) are 1 as described above, the equation 1 becomes a following equation 2.

Di(ΔM)=Di(0)+α(0)Co(0)ΔM−kCi(0)ΔM=Di(0)+α(0)ΔM−kΔM [Equation 2]

Since the Di(0) is Mi(0)Ci(0) and the Ci(0) is 1, the Di(0) becomes Mi(0).

The Mi(0) may be calculated through a following equation 3.

Mi(0)=pM0 [Equation 3]

Since the p and the M0 are initial input values, the Mi(0) may be calculated through the input values p and M0.

In addition, the α(0) may be calculated through a following procedure.

Since the silicon melted in the melting zone MZ is introduced into the growth zone GZ, as illustrated in FIG. 2, a level L of the melted silicon in the melting zone MZ is the same as a level L of the melted silicon in the growth zone GZ.

Accordingly, a ratio of variation in an amount of the silicon in the growth zone GZ to variation in an amount of the silicon in the melting zone MZ is Ai:Ao. In this case, the Ai:Ao may be expressed by a following equation 4.

Ai:Ao=(α−1)ΔM:(β−α)ΔM [Equation 4]

Since an amount of the silicon moved to the growth zone GZ from the melting zone MZ is αΔM, and a unit amount of the silicon used to grow the ingot IG in the growth zone GZ is ΔM, variation in the silicon in the growth zone GZ is (αΔM−ΔM), that is, (α−1)ΔM.

In addition, since an amount of the silicon fed into the melting zone MZ from the outside is βΔM, and an amount of the silicon moved to the growth zone GZ from the melting zone MZ is αΔM, variation in the silicon in the melting zone MZ becomes (βΔM−αΔM).

A α(0) may be calculated through a following equation 5 according to the equation 4.

α(M)=[Aiβ(M)+Ao]/(Ai+Ao)=β(M)+q

α(0)=[Aiβ(0)+Ao]/(Ai+Ao)=β(0)+q [Equation 5]

Since the q is 1−p, the α(0) may be calculated based on the initially input value p and the preset value β(0).

Accordingly, the Di(ΔM) of the equation 2 may be calculated based on the Mi(0) and the α(0) calculated through the equation 3 and the equation 5, respectively. Since the Ci is Di/Mi, a Ci(ΔM) may be expressed by a following equation 6.

Ci(ΔM)=Di(ΔM)/Mi(ΔM) [Equation 6]

After that, calculation of the Mi(ΔM) will be described.

Since βΔM is fed from the outside while the silicon of ΔM is used to grow the ingot IG, (β−1)ΔM may correspond to a variation amount of the silicon filled in the melting zone MZ and the growth zone GZ.

Accordingly, when the silicon of ΔM is used after the growth of the ingot IG starts, an amount of the silicon remaining in the melting zone MZ and the growth zone GZ becomes M0+(β−1)ΔM.

As a result, when the silicon with ΔM is used after the growth of the ingot IG starts, an amount Mi(ΔM) of the silicon remaining in the growth zone GZ may be calculated by a following equation 7.

Mi(ΔM)=p[M0+(β(0)−1)ΔM] [Equation 7]

The Ci(ΔM) of the equation 6 may be calculated through the equation 7.

Next, a method of calculating the Do and the Co will be described with reference to a following equation 8.

Do(M+ΔM)=Do(M)−α(M)Co(M)ΔM [Equation 8]

The Do(M+ΔM) represents the number of dopants in the melting zone MZ when the ingot is grown by M+ΔM. The Do(M) represents the number of dopants in the melting zone MZ when the ingot is grown by M.

In this case, since the number of dopants in the melting zone MZ is Do(ΔM) when a melted silicon is used by ΔM to grow the ingot IG after the growth of the ingot IG starts, and the Co(0) is 1 as described above, the equation 8 becomes a following equation 9.

Do(ΔM)=Do(0)−α(0)ΔM [Equation 9]

Since the Do(0) is Mo(0)Co(0) and the Co(0) is 1, the Do(0) becomes Mo(0).

The Mo(0) may be calculated through a following equation 10.

Mo(0)=qM0=(1−p)M0 [Equation 10]

Since the p and the M0 are initial input values, the Mo(0) may be calculated based on the initial input values p and M0. In this case, the α(0) may be calculated through the equation 4 and the equation 5 as described above.

Accordingly, the Do(ΔM) of the equation 9 may be calculated using the Mo(0) and the α(0) calculated through the equation 10 and the equation 5, respectively.

Since the Co is Do/Mo, a Co(ΔM) may be expressed by a following equation 11.

Co(ΔM)=Do(ΔM)/Mo(ΔM) [Equation 11]

After that, calculation of the Mo(ΔM) will be described.

As described above, a (β−1)ΔM corresponds to a variation amount of a silicon filled in the melting zone MZ and the growth zone GZ. When the silicon is used by ΔM after the growth of the ingot IG starts, a remaining amount of the silicon becomes M0+(β−1)ΔM.

Accordingly, when the silicon is used by ΔM after the growth of the ingot IG starts, a remaining amount Mo(ΔM) of the silicon may be calculated by a following equation 12.

Mo(ΔM)=q[M0+(β(0)−1)ΔM] [Equation 12]

The Co(ΔM) of the equation 11 may be calculated through the above equation 12.

The controller 240 may compare the calculated Ci(ΔM) with the initially preset Ci(0). Even if the Ci(ΔM) is less than the Ci(0), since a concentration of the dopant in the ingot IG is lower than a desired level if the feeding unit 130 maintains a feed amount or a feed rate of the silicon, the apparatus for manufacturing the ingot according to the embodiment of the present invention can reduce the feed amount of the silicon by reducing the feed rate of the silicon.

That is, if the Ci(ΔM) is less than the Ci(0), the controller 240 may calculate β(ΔM) by a following equation 13.

β(ΔM)=β(0)−Δβ(L_{MAX}/N_{MAX}) [Equation 13]

In this case, the Δβ is a unit variation amount of β which varies in order to reduce variation in a concentration of the dopant in the growth zone GZ. After the Δβ is derived by simulation before manufacturing the ingot IG, the Δβ may be stored in the memory 250. The (L_{MAX}/N_{MAX}) is used to normalize the Δβ.

For example, a plurality of Δβs are derived by simulation according to M0, R, k, and p. During the procedure, the Δβ may be derived according to a relation equation with respect to optimal M0, R, k, and p capable of maintaining a concentration of the dopant in the ingot IG.

A following equation represents an example of the Δβ derived by the simulation.

Δβ=[{a(R²/M0)}{b+ck}{d+ep+fp²}]^{1/3}

In this case, a, b, c, d, e, and f may be a constant.

In this manner, if the Ci(ΔM) is less than the Ci(0), the β(ΔM) becomes less than the β(0) through the equation 13. Further, if the Ci(ΔM) is not less than the Ci(0), the β(ΔM) may be maintained at β(0). After the β(ΔM) is calculated, the N becomes 1.

If the β(ΔM) is calculated, the controller 240 may calculate the feed rate. As described above, since dM_{F}/dt is β(dM/dt), dM_{F} (ΔM)/dt is β(ΔM) (dM/dt). The feed rate may be maintained when a growth amount of the ingot IG is in the range of ΔM to 2ΔM.

When the β(ΔM) is less than the β(0), the feed rate of the silicon is reduced so that a feed amount of the silicon per unit time may be also reduced.

In a next step, the equation 1 becomes Di(ΔM+ΔM)=Di(ΔM)+α(ΔM)Co(ΔM)ΔM−kCi(ΔM)ΔM, and the Di(ΔM), the Co(ΔM), and the Ci(ΔM) may use the results calculated in a previous step.

Further, in the equation 5, since α(M) is [Aiβ(M)+Ao]/(Ai+Ao)=β(M)+q, α(ΔM) is [Aiβ(ΔM)+Ao]/(Ai+Ao)=β(ΔM)+q. Since the β(ΔM) was calculated in a previous step, the α(ΔM) may be calculated.

In this case, Di(ΔM+ΔM), that is, Di(2ΔM) may be calculated using Di(ΔM), Co(ΔM), Ci(ΔM), and α(ΔM) calculated in a previous step.

Ci(2ΔM) may become Di(2ΔM)/Mi(2ΔM) through the equation 6, and Mi(2ΔM) may be calculated as Mi(ΔM)+β(β(ΔM)−1)ΔM through the equation 7. Accordingly, the Ci(2ΔM) may be calculated through the β(ΔM) which is calculated in a previous step.

In the same manner as a procedure of calculating Di(2ΔM) and Ci(2ΔM) using the values calculated in the previous step, Do(2ΔM) and Co(2ΔM) may be derived using the values calculated in the previous step.

The Do(ΔM+ΔM) becomes Do(ΔM)−α(ΔM)Co(ΔM)ΔM using the equation 8. Since Do(ΔM), α(ΔM), and Co(ΔM) may be derived in a previous step, the Do(2ΔM) may be obtained through the calculation result.

Further, the Co(2ΔM) becomes Do(2ΔM)/Mo(2ΔM) through the equation 11. In addition, the Mo(2ΔM) becomes Mo(ΔM)+q(β(ΔM)−1)ΔM through the equation 12. Since the β(ΔM) is obtained in a previous step, the Mo(2ΔM) may be calculated, and Co(2ΔM) may be calculated based on the Mo(2ΔM).

The controller 240 may compare the Ci(2ΔM) obtained by the above calculation with the Ci(ΔM) obtained in the previous step. If the Ci(2ΔM) is less than the Ci(ΔM), an amount of the silicon fed into the melting zone MZ has to be reduced in order to maintain a concentration of the dopant in the ingot IG. Accordingly, the β should be reduced, and the β(2ΔM) becomes β(ΔM)−Δβ(L_{MAX}/N_{MAX}). Since the β(ΔM) is obtained in the previous step and the Δβ is a previously stored value, the β(2ΔM) may be calculated.

Since dM_{F}/dt is βdM/dt, dM_{F}(2ΔM)/dt may be calculated as β(2ΔM)dM/dt. The feed rate may be maintained when a growth amount of the ingot is in the range of 2ΔM to 3ΔM. In this manner, the above calculation is repeated until N becomes N_{MAX}, the feed rate of the silicon with respect to a full process may be obtained.

As shown in FIG. 2, since a feed amount M_{F} of the silicon fed from the feeding unit 130 is βΔM when the ingot is grown by ΔM, a feed amount M_{F}(2ΔM) of the silicon fed from the feeding unit 130 at N=2 becomes β(2ΔM)ΔM.

That is, the apparatus for manufacturing the ingot according to the embodiment of the present invention may reduce the feed amount M_{F} of the silicon as the Ci is reduced during a procedure of growing the ingot IG.

As explained with reference to FIG. 3, a growth rate dM/dt of the ingot may be input to the controller 240. A value of the dM/dt may be updated to another value or may be maintained. In this case, the value of the dM/dt may be updated at any time during a process of manufacturing the ingot IG.

The above mentioned feeding coefficient β may be a ratio of the feed rate dM_{F}/dt to the growth rate dM/dt of the ingot. Accordingly, as the feeding coefficient β varies, the feed rate dM_{F}/dt of the silicon may vary. When the β is reduced as the ingot IG is grown, the feed rate dM_{F}/dt of the silicon may be reduced.

Variation in the β is achieved according to a concentration Ci of the dopant in the growth zone GZ, if the concentration Ci of the dopant in the growth zone GZ is reduced during a procedure of growing the ingot IG, the feeding coefficient β is reduced. Accordingly, a feed amount M_{F} (=βΔM) of the silicon and a feed rate dM_{F}/dt(=β(dM/dt)) of the silicon may be reduced.

In this manner, the procedure may be repeated by N=3, 4, . . . , (N_{MAX}−1).

The above procedure may be achieved during a procedure of manufacturing the ingot. The ingot may be manufactured by controlling the feed rate according to β(ΔM), β(2ΔM), . . . , β((N_{MAX}−1)ΔM) derived during the procedure of manufacturing the ingot.

In contrast, the previously derived β(ΔM), β(2ΔM), . . . , β((N_{MAX}−1)ΔM) are programmed and stored in the memory 250. During the procedure of manufacturing the ingot, the controller 240 may control the feed rate of the silicon according to the stored β values without calculating the β.

The apparatus for manufacturing the ingot according to the embodiment of the present invention operating as described above may maintain the concentration of the dopant in the ingot IG by varying the feed rate of the silicon fed from the feeding unit 130 according to the concentration of the dopant in the growth zone GZ.

Meanwhile, because the feed rate dMF/dt of the silicon is β(0) (dM/dt) at initial growth of the ingot IG, when β(0) is smaller than 1, the feed rate of the silicon is less than of the growth rate of the ingot IG so that a level L of the melted silicon may be lower than a proper level.

In addition, during a procedure of growing the ingot IG, since the feeding coefficient β is reduced according to the concentration of the dopant, it may be difficult to control a level L of the meted silicon as a proper level when β(0) is less than 1.

If β(0) is equal to or greater than 1, the feed rate of the silicon is equal to or greater than the growth rate of the ingot IG when growth of the ingot IG starts. Accordingly, it may be easy to control a proper level L of the melted silicon to grow the ingot IG.

Meanwhile, as a segregation coefficient k of the dopant is smaller, feeing of the dopant into the melting zone MZ may stop or the number of times in feeding of the dopant may be reduced.

The segregation coefficient may vary according to the dopant. For example, segregation coefficients of phosphorus and boron are 0.35 and 0.8, respectively. When the ingot is grown by ΔM, an amount of the boron remaining in the growth zone GZ may be less than an amount of the phosphorus.

As a result, in a case of dopant having a great segregation coefficient, an amount of the dopant remaining in the growth zone GZ is small as the ingot IG is grown. Accordingly, when the feeding unit 130 continuously feeds the silicon, the concentration of the dopant may be excessively reduced.

Accordingly, the apparatus for manufacturing the ingot according to the embodiment of the present invention may maintain the concentration of the dopant by increasing the number of times of feeding of the dopant as a segregation coefficient of the dopant is greater while the ingot IG is grown.

For example, since the segregation coefficient of boron is greater than the segregation coefficient of phosphorus, the number of times of feeding of boron is greater than that of phosphorus while the ingot IG is grown.

In this case, when the dopant has a segregation coefficient less than 0.4 like the phosphorus, after the dopant is fed into the crucible 110 before the ingot IG is grown, the feeding of the dopant may stop until growth of the ingot IG is completed.

Since a segregation coefficient of dopant such as the phosphorus is less than 0.4, even if the feeding coefficient is reduced according to growth of the ingot IG or feeding of the silicon is reduced according to concentration of the dopant, the concentration of the dopant may not be excessively reduced.

Accordingly, since the concentration of the dopant may maintain while the ingot IG is grown, feeding of the dopant may stop while the ingot IG is grown.

FIG. 4 is a view illustrating a modified example of the apparatus for manufacturing an ingot according to an exemplary embodiment of the present invention. As shown in FIG. 4, the apparatus for manufacturing the ingot according to the embodiment of the present invention may further include a dopant feeder 260, a dopant feed pipe 270, and a valve 220.

The dopant feeder 260 may store and feed the dopant. The dopant feeder 260 may include a load lock (not shown) to feed the dopant at least one time.

The dopant feed pipe 270 may connect the feeding unit 130 to the dopant feeder 260. The valve 220 to control feeding of the dopant may be installed at the dopant feed pipe 270. The valve 220 may be opened and closed and an opening/closing amount of the valve 220 may be determined according to a valve control signal from the controller 240.

In the foregoing description, although the value 220 to feed the dopant is opened or closed under control of the controller 240, the valve 220 may be opened or closed by an operator.

Since the dopant feed pipe 270 is connected to the feeding unit 130, the dopant may be fed into the melting zone MZ through the feeding unit 130. Accordingly, in order to feed the dopant into the melting zone MZ, since a separate device may not be included in addition to the feeding unit 130, a configuration of the apparatus for manufacturing the ingot may be simplified.

Meanwhile, when the dopant is a material such as boron, the dopant may be fed into the melting zone MZ at least one time while the ingot IG is grown.

As described above, a concentration of dopant such as boron having a segregation coefficient of 0.4 or greater may be excessively reduced as the ingot IG is grown. Accordingly, when the dopant has a segregation coefficient of 0.4 or greater, so as to maintain a concentration of the dopant while the ingot IG is grown, the dopant may be fed into the melting zone MZ at least one time while the ingot IG is grown.

Meanwhile, as described above, dopant used to grow a silicon ingot has a segregation coefficient less than 1. Accordingly, if the ingot starts to be grown, some of the dopant is moved to the ingot IG but the rest of the dopant remains in the growth zone GZ.

Due to the dopant remaining in the growth zone GZ, the concentration of the dopant in the growth zone GZ may be higher than a desired concentration in initial growth of the ingot IG.

When the ingot IG is grown during a first time period and a second time period which is a consecutive period of the first time period, a level L of the melted silicon of FIG. 2 may be gradually increased during the first time period and may be gradually reduced during the second time period by setting an initial value β(0) of the ratio of a feed rate of the silicon to a growth rate of the ingot greater than 1.

Since β(0) greater than 1 means that a feed rate of the silicon is greater than the growth rate of the ingot IG, a part of the fed silicon is used to grow the ingot IG but the rest of the fed silicon remains in the melting zone MZ and the growth zone GZ.

Accordingly, due to the silicon remaining in the melting zone MZ and the growth zone GZ, the melted silicon may be increased in initial growth of the ingot IG.

When an initial value of a level L of the melted silicon is L0, a level L of the melted silicon may be greater than L0 in initial growth of the ingot IG due to increase of the melting silicon.

That is, the level L of the melted silicon may be gradually increased during the first time period. In this manner, since the melted silicon is increased, the concentration of the dopant may be prevented from being increased or the amount of increment of the concentration may be reduced in initial growth of the ingot IG.

After that, during the second time period, as described above, since the feed rate of the silicon is less than the growth rate of the ingot by controlling the feeding coefficient, a level L of the melted silicon is gradually reduced.

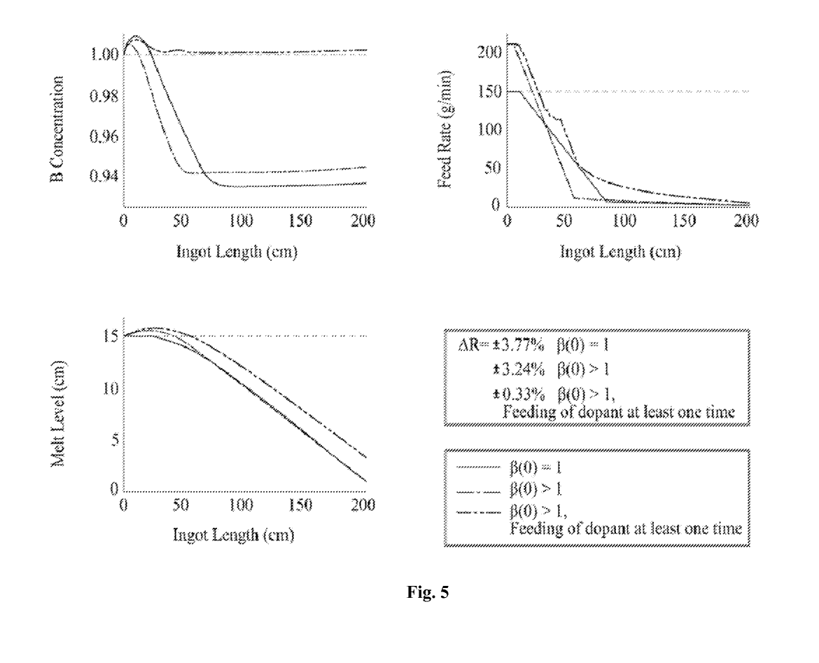

FIG. 5 is graphs illustrating variation in a concentration of dopant according to fed dopant. In FIG. 5, a solid line, an alternated long and short dash line and an alternate long and two short dashes line correspond to cases of β(0)=1, β(0)>1, and β(0)>1 with feeding the dopant at least one time, respectively.

In this case, a graph of FIG. 5 is derived in a condition that k=0.8, M0=120 kg, p=0.714, an initial melt level L0=15 cm, a growth rate of the ingot is constant, and the dopant is fed 10 times in initial growth of the ingot IG.

As illustrated in the solid line and the alternated long and short dash line, when boron is not fed while the ingot IG is grown, the concentration of the boron in the growth zone GZ is rapidly reduced. In contrast, as illustrated in the alternate long and two short dashes line, when the boron is fed at least one time while the ingot IG is grown, the concentration of the boron in the growth zone GZ is maintained.

In this manner, when the boron is fed at least one time, variation ΔR of the resistivity of the ingot IG is ±0.33%. When the boron is not fed, the variation ΔR of the resistivity of the ingot IG is ±3.77% and ±3.24%. Accordingly, the variation ΔR of the resistivity of the ingot IG when the boron is fed at least one time is much smaller than the variation ΔR of the resistivity of the ingot IG when the boron is not fed.

Further, when the dopant is fed at least one time, a level L of the melted silicon after the growth of the ingot is completed is 3.13 cm. Otherwise, when the dopant is not fed, a level L of the melted silicon after the growth of the ingot is completed is in the range of 0.8 cm to 0.9 cm.

The level L of the melted silicon in case that the dopant is fed at least one time is greater than the level L of the melted silicon in case that the dopant is not fed.

Accordingly, a stable process of manufacturing the ingot is possible in a case where the dopant is fed at least one time as compared with a case where the dopant is not fed.

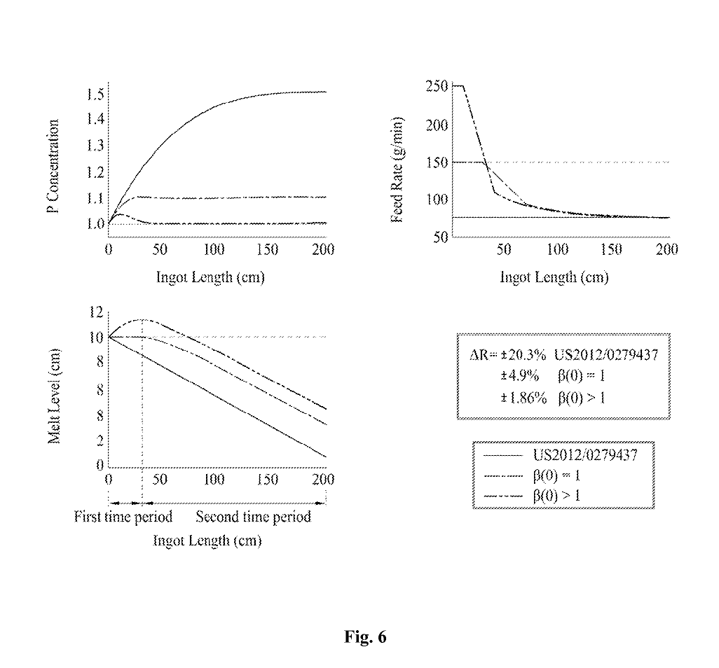

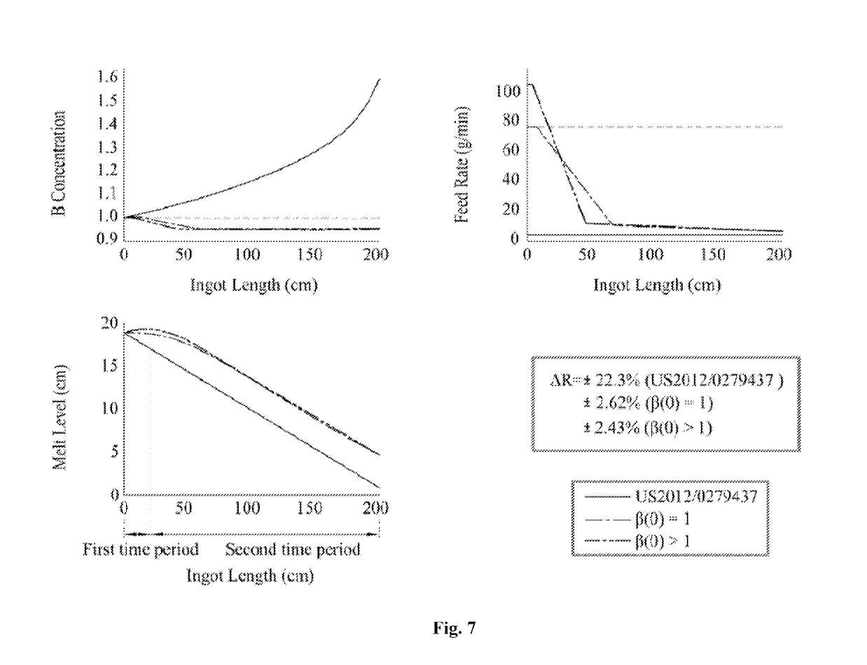

FIGS. 6 and 7 are graphs illustrating a concentration of dopant, a feed rate of silicon, and a height of melted silicon in an operation of the apparatus for manufacturing an ingot according to an exemplary embodiment of the present invention.

An alternated long and short dash line of the graphs shown in FIGS. 6 and 7 correspond to a case where an initial value β(0) of the feeding coefficient, that is, β(0)=1 and the feeding coefficient β varies according to the concentration of the dopant. An alternate long and two short dashes line of the graphs shown in FIGS. 6 and 7 correspond to a case where an initial value β(0) of the feeding coefficient, that is, β(0)>1 and the feeding coefficient β varies according to the concentration of the dopant.

In this case, the solid lines of the graphs shown in FIGS. 6 and 7 are obtained from US Patent Application Publication No. 2012/0279437.

In US Patent Application Publication No. 2012/0279437, a silicon is fed with a feed rate dM_{F}/dt=(dM/dt)[1−k{(Ai+Ao)/Ai}]. In this case, since the k, the Ai, and the Ao are a constant, the feeding coefficient [1−k{(Ai+Ao)/Ai}] is also a constant so that a ratio of the feed rate of the silicon to a growth rate of the ingot IG is constant.

In contrast, according to the apparatus for manufacturing the ingot in accordance with the embodiment of the present invention, as described above, an initial value of the feeding coefficient is 1 or greater and the feeding coefficient is changed during the growth of an ingot IG.

Accordingly, the feed rate of the silicon described in US Patent Application Publication No. 2012/0279437 is fixed to a constant value during the growth of the ingot IG.

In contrast, according to the apparatus for manufacturing the ingot of the embodiment of the present invention, the feed rate of the silicon may vary during the growth of the ingot IG according to the feeding coefficient.

The graph shown in FIG. 6 is derived in a condition that the dopant is phosphorus, k=0.35, M0=80 kg, p=0.714, an initial melt level L0=10 cm, ΔM=0.1 kg, and a growth rate of the ingot is constant. In this case, when β(0)=1, A is set as Δβ=0.001193. When β(0)=1.677, the A is set as Δβ=0.003183.

The graph shown in FIG. 7 is derived in a condition that the dopant is boron, k=0.8, M0=150 kg, p=0.83, the initial melt level L0=18.75 cm, ΔM=0.1 kg, and a growth rate of the ingot is constant. In this case, when β(0)=1, A is set as Δβ=0.001379. When β(0)=1.381, the A is set as Δβ=0.002757.

As described above, some of the dopant is distributed into the ingot IG according to the segregation coefficient of the dopant but the rest of the dopant remains in the growth zone GZ. Accordingly, the concentration of the dopant in the growth zone GZ may be higher than a desired concentration in initial growth of the ingot IG.

In a case of US Patent Application Publication No. 2012/0279437, since a feeding coefficient [1−k{(Ai+Ao)/Ai}] of the phosphorus is fixed at 0.51 and a feeding coefficient [1−k{(Ai+Ao)/Ai}] of the boron is fixed at 0.04 while the ingot is grown from the beginning, it may be understood that a concentration of the dopant in the growth zone GZ is gradually increased. Accordingly, in US Patent Application Publication No. 2012/0279437 fixing the feeding coefficient, it may be difficult to control the concentration of the dopant.

As shown in FIG. 6, when an initial value β(0) of the feeding coefficient, that is β(0)=1 and the feeding coefficient β varies according to the concentration of the dopant afterward, if the feed rate of the silicon is the same as the growth rate of the ingot in the initial growth of the ingot IG, that is, in the first time period, it may be understood that the concentration of the dopant in the growth zone GZ is gradually increased. Next, it may be understood that the concentration of the dopant increased during the second time period is maintained.

In this case, since α(0) is 1, that is, the feed rate of the silicon is the same as the growth rate of the ingot, the level L of the melted silicon during the first time period is maintained constant. Next, since the feeding coefficient varies according to the concentration of the dopant so that feeding of the silicon is reduced, the level L of the melted silicon is reduced during the second time period.

Meanwhile, when the initial value of the feeing coefficient is β(0)>1 and the feeding coefficient β varies according to the concentration of the dopant, since the feed rate of the silicon is greater than the growth rate of the ingot IG in an initial growth of the ingot IG, that is, during the first time period, some of the fed silicon is used to grow the ingot IG and the rest of the fed silicon remains in the melting zone MZ and the growth zone GZ.

Accordingly, although a part of the dopant remains in the growth zone GZ according to the segregation coefficient, increase in the concentration of the dopant may be limited due to a silicon fed more than a used amount required to grow the ingot IG.

Accordingly, during the first time period, it may be understood that the concentration of the dopant is increased and is then reduced, and the reduced concentration of the dopant is maintained during the second time period. Accordingly, the initial value of the feeding coefficient is β(0)>1 and the feeding coefficient β varies according to the concentration of the dopant afterward, it may be understood to stably control the concentration of the dopant.

In this case, since β(0) is greater than 1, that is, the feed rate of the silicon is greater than the growth rate of the ingot, the level L of the melted silicon during the first time period is increased. Next, since the feeding coefficient varies according to the concentration of the dopant and feeding of the silicon is reduced, the level L of the melted silicon during the second time period is reduced.

As shown in FIG. 6, according to US Patent Application Publication No. 2012/0279437, when the concentration of the phosphorus is controlled, the variation ΔR in the resistivity is ±20.3%. When β(0)=1 and the β varies to control the concentration of the phosphorus during a procedure of growing the ingot IG, ΔR is ±4.9%. In addition, When β(0)>1 and the β varies to control the concentration of the phosphorus during a procedure of growing the ingot IG, ΔR is ±1.86%.

Accordingly, when the concentration of the phosphorus is controlled with β(0)>1, it may be understood that the resistivity of the ingot is stably maintained.

In addition, as shown in FIG. 7, according to US Patent Application Publication No. 2012/0279437, when the concentration of the boron is controlled, the variation ΔR in the resistivity is ±22.3%. When β(0)=1 and the β varies so that the concentration of the phosphorus is controlled during a procedure of growing the ingot IG, ΔR is ±2.62%. In addition, When β(0)>1 and the β varies so that the concentration of the phosphorus is controlled during a procedure of growing the ingot IG, ΔR is ±2.43%.

Accordingly, when the concentration of the phosphorus is controlled with β(0)>1, it may be understood that the resistivity of the ingot is stably maintained.

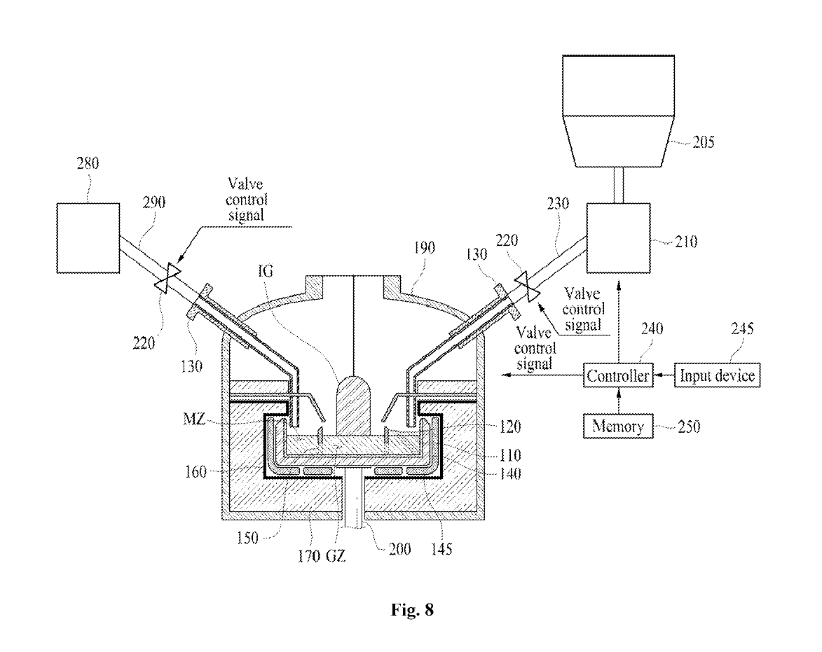

FIG. 8 is a view illustrating a modified example of the apparatus for manufacturing an ingot according to an exemplary embodiment of the present invention. The apparatus for manufacturing an ingot according to an exemplary embodiment of the present invention may further include a second hopper 280.

After growth of the ingot IG is completed, the second hopper 280 may feed silicon stored in the second hopper 280 into the crucible 110.

As shown in FIG. 8, although the second hopper 280 may be connected to another feeding unit 130 different from the feeding unit 130 connected to the first hopper 205, the second hopper 280 may be connected to the feeding unit 130 connected to the first hopper 205.

In this case, a hopper feed rate of the silicon fed from the second hopper 280 may be greater than a regulation feed rate of the silicon from the feed regulator 210. The hopper feed rate may be a rate when the silicon fed from the second hopper 280 enters the feeding unit 130. Further, the regulation feed rate may be a rate when the silicon fed from the feed regulator 210 enters the feeding unit 130.

The apparatus for manufacturing the ingot according to the embodiment of the present invention may reduce a feed rate of the silicon by varying the feeding coefficient β according to a concentration during a procedure of growing the ingot IG.

Accordingly, since the level L of the melted silicon is gradually reduced during the growth of the ingot IG, the silicon should be additionally fed so that the level L of the melted silicon is increased to a proper level L in order to grow a next ingot.

Since the feed regulator 210 regulates the feed rate of the silicon by regulating the regulation feed rate, when the silicon is fed through the feed regulator 210, a long time may be taken.

In contrast, if a valve 220 included in a hopper silicon feed pipe 290 is opened according to a valve control signal from the controller 240, the silicon stored in the second hopper 280 may be fed into the crucible 110 with the hopper feed rate higher than the regulation feed rate.

Meanwhile, as explained with reference to FIG. 4, although the dopant feed pipe 279 is connected to the feeding unit 130 which is connected to the silicon feed pipe 230, the dopant feed pipe 270 may be connected to the feeding unit 130 which is connected to the hopper silicon feed pipe 290 of FIG. 8.

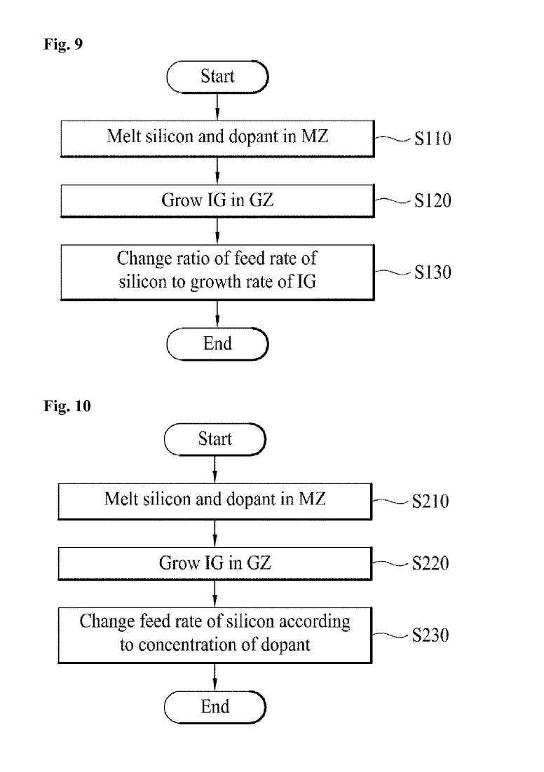

FIGS. 9 and 10 are flowcharts illustrating a method of manufacturing an ingot according to an exemplary embodiment of the present invention.

The method of manufacturing the ingot according to the embodiment of the present invention can intermittently or continuously feed the silicon while the ingot IG is grown.

As shown in FIG. 9, the method of manufacturing the ingot according to the embodiment of the present invention includes melting silicon and dopant in a melting zone MZ between a crucible 110 and an inner wall 120 surrounded by the crucible 110 (S110), growing an ingot IG in a growth zone GZ of the inner wall 120 by introducing the silicon and the dopant melted in the growth zone GZ (S120), and changing a ratio of a feed rate of the silicon fed into the melting zone MZ to a growth rate of the ingot IG (S130).

As shown in FIG. 10, the method of manufacturing the ingot according to the embodiment of the present invention includes melting silicon and dopant in a melting zone MZ between a crucible 110 and an inner wall 120 surrounded by the crucible 110 (S210), growing an ingot IG in a growth zone GZ of the inner wall 120 by introducing the silicon and the dopant melted in the growth zone GZ (S220), and changing a feed rate of the silicon fed into the melting zone MZ according to a concentration in the growth zone GZ (S230).

Although exemplary embodiments of the present invention have been described in detail hereinabove, it should be clearly understood that many variations and modifications of the basic inventive concepts herein taught which may appear to those skilled in the present art will still fall within the spirit and scope of the present invention, as defined in the appended claims.

What is claimed is:

1. An apparatus for manufacturing an ingot to intermittently or continuously feed silicon while an ingot is grown, the apparatus comprising:
a crucible having a melting zone in which the silicon and dopant are melted;
an inner wall surrounded by the crucible, and having a growth zone in which the silicon and the dopant melted in the crucible are introduced so that the ingot is grown in the inner zone; and
a feeding unit feeding the silicon into the melting zone,
wherein a ratio of a feed rate of the silicon fed through the feeding unit to a growth rate of the ingot is changed.

2. The apparatus of claim 1, wherein the feeding unit reduces a feed amount of the silicon when a concentration of the dopant in the growth zone is reduced during a procedure of growing the ingot.

3. The apparatus of claim 2, wherein as a segregation coefficient of the dopant is smaller, feeding of the dopant into the melting zone stops or the number of times of the feeding of the dopant is reduced.

4. The apparatus of claim 3, wherein the dopant has a segregation coefficient less than 0.4, and the feeding of the dopant stops while growth of the ingot is completed after the dopant is fed into the crucible before the ingot is grown.

5. The apparatus of claim 3, wherein the dopant has a segregation coefficient of 0.4 or greater, and the dopant is fed into the melting zone at least one time while the ingot is grown.

6. The apparatus of claim 1, wherein the dopant is fed into the melting zone through the feeding unit.

7. The apparatus of claim 1, wherein a concentration of the dopant in the ingot is maintained by varying the feed rate of the silicon fed from the feeding unit according to the concentration of the dopant of the growth zone.

8. The apparatus of claim 1, wherein, when the ingot is grown during a first time period and a second time period which is a consecutive period to the first time period, a level of the melted silicon is gradually increased during the first time period, and is gradually reduced during the second time period.

9. The apparatus of claim 8, wherein an initial value of the ratio is greater than 1.

10. The apparatus of claim 1, further comprising:
a feed regulator which is connected to the feeding unit, to regulate a feed amount of the silicon;
a first hopper which is connected to the feed regulator, to store the silicon; and
a second hopper to feed silicon stored in the second hopper into the crucible after the growth of the ingot is completed,
wherein a hopper feed rate of the silicon fed from the second hopper is greater than a regulation feed rate of the silicon fed from the feed regulator.

11. An apparatus for manufacturing an ingot to intermittently or continuously feed silicon while an ingot is grown, the apparatus comprising:
a crucible having a melting zone in which the silicon and dopant are melted;
an inner wall surrounded by the crucible, and having a growth zone in which the silicon and the dopant melted in the crucible are introduced so that the ingot is grown in the growth zone; and
a feeding unit feeding the silicon into the melting zone with a feed rate varying according to a concentration of the dopant in the inner wall.

12. The apparatus of claim 11, wherein the feed rate is reduced when a concentration of the dopant in the growth zone is reduced during a procedure of growing the ingot.

13. The apparatus of claim 12, wherein, as a segregation coefficient of the dopant is smaller, feeding of the dopant into the melting zone stops or the number of times of the feeding of the dopant is reduced.

14. The apparatus of claim 12, wherein the dopant has a segregation coefficient of 0.4 or greater, and the dopant is fed into the melting zone at least one time while the ingot is grown.

15. The apparatus of claim 13, wherein the dopant has a segregation coefficient less than 0.4, and the feeding of the dopant stops while the growth of the ingot is completed after the dopant is fed into the crucible before the ingot is grown.

16. The apparatus of claim 11, wherein when the growth of the ingot starts, the feed rate is equal to or greater than a growth rate of the ingot.

17. The apparatus of claim 11, wherein the dopant is fed into the melting zone through the feeding unit.

18. The apparatus of claim 11, wherein a concentration of the dopant in the ingot is maintained by varying the feed rate of the silicon fed from the feeding unit according to the concentration of the dopant of the growth zone.

19. The apparatus of claim 11, wherein, when the ingot is grown during a first time period and a second time period which is a consecutive period to the first time period, a level of the melted silicon is gradually increased during the first time period, and is gradually reduced during the second time period.

20. The apparatus of claim 11, further comprising:
a feed regulator connected to the feeding unit to control a feed amount of the silicon;
a first hopper connected to the feed regulator to store the silicon; and
a second hopper to feed silicon stored in the second hopper into the crucible after the growth of the ingot is completed,
wherein a hopper feed rate of the silicon fed from the second hopper is greater than a regulation feed rate of the silicon fed from the feed regulator.

21. A method of manufacturing an ingot to intermittently or continuously feed silicon while an ingot is grown, the method comprising:
melting the silicon and dopant in a melting zone between a crucible and an inner wall surrounded by the crucible;
growing an ingot in a growth zone of the inner wall by introducing the melted silicon and dopant in the growth zone; and
changing a ratio of a feed rate of the silicon fed into the melting zone to a growth rate of the ingot.

22. A method of manufacturing an ingot to intermittently or continuously feed silicon while an ingot is grown, the method comprising:
melting the silicon and dopant in a melting zone between a crucible and an inner wall surrounded by the crucible;
growing an ingot in a growth zone of the inner wall by introducing the melted silicon and dopant in the growth zone; and
changing a feed rate of the silicon fed into the melting zone according to a concentration of the dopant in the growth zone.
